(19) United States
(12) Patent Application Publication
(10) Pub. No.: US 2012/0252155 A1
(43) Pub. Date: Oct. 4, 2012

(54) METHOD OF IMPLANTING IMPURITIES AND METHOD OF MANUFACTURING A COMPLEMENTARY METAL OXIDE SEMICONDUCTOR (CMOS) IMAGE SENSOR USING THE SAME

(76) Inventors: Sang-Jun CHOI, Yongin-si (KR); June-Mo Koo, Suwon-si (KR); Duck-Hyung Lee, Seongnam-si (KR); Jong-Cheol Shin, Hwaseong-si (KR); Yu-Jin Ahn, Seongnam-si (KR); Eun-Kyung Park, Seoul (KR); Sun-E Park, Daejeon (KR)

(21) Appl. No.: 13/428,792

(22) Filed: Mar. 23, 2012

(30) Foreign Application Priority Data
Mar. 29, 2011 (KR) 10-2011-0027899

(51) Int. Cl. H01L 31/18; H01L 21/04

(52) U.S. Cl. 438/70; 438/510; 257/E21.04; 257/E31.127

(57) ABSTRACT

In a method of doping impurities, an amorphous layer is formed on a substrate. Impurities are implanted through a top surface of the amorphous layer to form a first doping region at an upper portion of the substrate. The first doping region and the amorphous layer are transformed into a second doping region and a recrystallized layer, respectively, by a laser annealing process. The recrystallized layer is removed.

### CROSS-REFERENCE TO RELATED APPLICATION

This application claims priority under 35 USC§119 to Korean Patent Application No. 10-2011-0027899, filed on Mar. 29, 2011, the disclosure of which is hereby incorporated by reference herein in its entirety.

### BACKGROUND

1. Technical Field

Example embodiments relate to methods of implanting impurities and methods of manufacturing a complementary metal oxide semiconductor (CMOS) image sensor using the same. More particularly, example embodiments relate to methods of manufacturing a CMOS image sensor including a backside illumination (BSI) structure and methods of implanting impurities used in the same.

2. Description of the Related Art

In a CMOS image sensor having a front-side illumination structure, an optical signal loss may occur due to metal wirings. To prevent this difficulty, a CMOS image sensor having a baskside illumination (BSI) structure has been developed. In a method of manufacturing the CMOS image sensor including the BSI structure, a photodiode may be formed at an upper portion of a substrate, and circuit elements and metal wirings may be formed on a first surface of the substrate to be electrically connected to the photodiode. After grinding a second surface of the substrate opposing the first surface to have a thickness of about several micrometers, a color filter and a lens may be formed on the ground second surface of the substrate. A light may enter through the second surface of the substrate, so that the optical signal loss may be reduced.

In the process of grinding the substrate, a defect of the substrate, e.g. a dangling bond of silicon and hydrogen, may be relatively easily generated. Electrons may be emitted from the dangling bond, so that a dark current or a white spot may occur, thereby deteriorating the photosensitivity of the CMOS image sensor.

### SUMMARY

Example embodiments provide a method of implanting impurities at a relatively low temperature for manufacturing a CMOS image sensor having a BSI structure.

Example embodiments provide a method of manufacturing a CMOS image sensor having a BSI structure using the method of implanting impurities.

According to an example embodiment, there is provided a method of implanting impurities. In the method, an amorphous layer is formed on a substrate. Impurities are implanted through a top surface of the amorphous layer to form a first doping region at an upper portion of the substrate. The first doping region and the amorphous layer are transformed into a second doping region and a recrystallized layer, respectively, by a laser annealing process. The recrystallized layer is removed.

In an example embodiment, the amorphous layer may be formed at a temperature below about 450° C. by one of a chemical vapor deposition process, an atomic layer deposition process, or a sputtering process.

In an example embodiment, the amorphous layer may be formed to have a thickness of about 2 nm to about 100 nm.

In an example embodiment, the amorphous layer may be formed to include one of silicon, germanium, or silicon germanium.

In an example embodiment, the impurities are formed of a material which may include boron, arsenic, or phosphorous.

In an example embodiment, the laser annealing process may include irradiating a laser having an energy of about 1 J/cm2 to about 5 J/cm2 onto the top surface of the amorphous layer.

In an example embodiment, the second doping region may have a thickness larger than a thickness of the first doping region.

In an example embodiment, removing the recrystallized layer may include performing a wet etching process on the recrystallized layer.

In an example embodiment, removing the recrystallized layer may include planarzing an upper portion of the recrystallized layer by a chemical mechanical polishing process.

In an example embodiment, the substrate may include single crystalline silicon.

According to an example embodiment, there is provided a method of manufacturing a complementary metal oxide semiconductor (CMOS) image sensor. In the method, a photodiode and a circuit element are formed on a first surface of a substrate. The circuit element is electrically connected to the photodiode. An amorphous layer is formed on a second surface of the substrate opposing the first surface. Impurities are implanted through a top surface of the amorphous layer to form a first doping region at an upper portion of the substrate. The first doping region and the amorphous layer are transformed into a second doping region and a recrystallized layer, respectively, by a laser annealing process. The recrystallized layer is removed.

In an example embodiment, prior to forming the amorphous layer on the second surface of the substrate, the second surface of the substrate may be further grinded.

In an example embodiment, after removing the recrystallized layer, a color filter and a microlens may be further formed on the second surface of the substrate.

In an example embodiment, the amorphous layer may be formed using one of silicon, germanium, or silicon germanium at a temperature below about 450° C. by one of a CVD process, an ALD process, or a sputtering process.

In an example embodiment, the amorphous layer may be formed to have a thickness of about 2 nm to about 100 nm.

In an example embodiment, the impurities are formed of a material which may include one of boron, arsenic, or phosphorous.

In an example embodiment, the laser annealing process may include irradiating a laser having an energy of about 1 J/cm² to about 5 J/cm² onto the top surface of the amorphous layer, and the laser.

In an example embodiment, the second doping region may have a thickness larger than a thickness of the first doping region.

In an example embodiment, the removing of the recrystallized layer may include a wet etching process or a chemical mechanical polishing process.

In an example embodiment, the substrate may include single crystalline silicon.

According to an example embodiment, a method of manufacturing a complementary metal oxide semiconductor (CMOS) image sensor is provided. The method includes forming a gate structure comprising a gate insulating layer and a gate electrode sequentially stacked on a first surface of a first substrate in each of an active pixel sensor array region and a peripheral circuit region of the first substrate, forming a photodiode on the first surface of the first substrate in the active pixel sensor array region, and implanting first impurities into an upper portion of the first surface of the first substrate adjacent to a sidewall of the gate electrode in the active pixel sensor array region and into an upper portion of the first surface of the first substrate adjacent to opposing sidewalls of the gate electrode in the peripheral region to form a first impurity region in the active pixel sensor array region and a second impurity region in the peripheral circuit region. The gate structure and the first impurity region in the active pixel sensor array region are electrically connected to the photodiode. The method further includes forming a first insulating interlayer covering the gate electrodes in the active pixel sensor array region and the peripheral circuit region, forming a first contact plug in the first insulating interlayer in the active pixel sensor array region and a first wiring connected to the first contact plug and on the first insulating interlayer and the first contact plug and forming a second contact plug in the first insulating interlayer in the peripheral circuit region and a second wiring connected to the second contact plug and on the first insulating interlayer and the second contact plug. The first contact plug and the first wiring are electrically connected to the first impurity region in the active pixel sensor array region and the second contact plug and the second wiring are electrically connected to the second impurity region in the peripheral circuit region.

The method further includes forming a protection layer on the first insulating interlayer to cover the first and second wirings in the active pixel sensor region and the peripheral circuit region, forming a second substrate on a top surface of the protection layer, turning the first substrate having the first and second wirings and the second substrate formed thereon upside down, removing a portion of a second surface of the first substrate opposing the first surface, forming an amorphous layer on the second surface of the first substrate at a temperature below about 450° C., implanting second impurities through a top surface of the amorphous layer to form a first doping region at the second surface of the first substrate and the second impurities implanted into the top surface of the amorphous layer are formed of a material which does not include fluoride, transforming the first doping region and the amorphous layer into a second doping region and a recrystallized layer, respectively, by a laser annealing process and removing the recrystallized layer.

According to an example embodiment, when manufacturing a CMOS image sensor, an amorphous layer may be formed on a second surface of a substrate having wirings on a first surface of the substrate opposing the second surface. The amorphous layer is formed on the second surface of the substrate at a temperature below about 450° C. A first doping region may be formed by implanting impurities, e.g. boron, through the amorphous layer into an upper portion of the substrate. The impurities in the first doping region may be activated through a laser annealing process, so that a second doping region may be formed to have a desired thickness. The laser annealing process may not be performed at a relatively high temperature, so that the wirings on the substrate may not be damaged by the laser annealing process. Further, the impurities may not include a material including fluoride (F) such as, e.g. boron fluoride (BF₂), so that a defect, e.g. a slip dislocation, may not be generated in the substrate. Moreover, an occurrence of a dark current or a white spot may be suppressed.

### BRIEF DESCRIPTION OF THE DRAWINGS

Example embodiments can be understood in more detail from the following detailed description taken in conjunction with the accompanying drawings. FIGS. 1 to 19 represent non-limiting, example embodiments as described herein.

FIGS. 1 to 4 are cross-sectional views illustrating a method of implanting impurities in accordance with an example embodiment;

FIGS. 5A to 5B are cross-sectional views illustrating a method of implanting impurities in accordance with a comparative embodiment; and

FIGS. 6 to 13 are cross-sectional views illustrating a method of manufacturing a CMOS image sensor in accordance with an example embodiment.

### DETAILED DESCRIPTION OF EXAMPLE EMBODIMENTS

Various example embodiments will be described more fully hereinafter with reference to the accompanying drawings, in which example embodiments are shown. Example embodiments of the present inventive concept may, however, be embodied in many different forms and should not be construed as limited to example embodiments set forth herein.

It will be understood that when an element or layer is referred to as being “on,” “connected to” or “coupled to” another element or layer, it can be directly on, connected or coupled to the other element or layer or intervening elements or layers may be present. Like numerals refer to like elements throughout. As used herein, the term “and/or” includes any and all combinations of one or more of the associated listed items.

Hereinafter, example embodiments will be explained in detail with reference to the accompanying drawings.

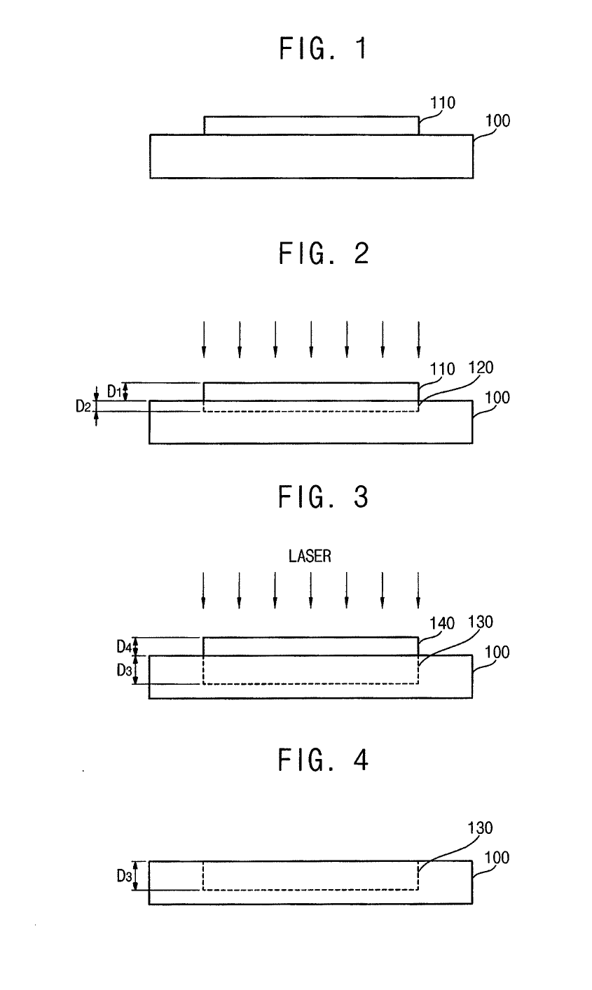

FIGS. 1 to 4 are cross-sectional views illustrating a method of implanting impurities in accordance with an example embodiment.

Referring to FIG. 1, an amorphous layer 110 may be formed on a substrate 100.

The substrate 100 may include a semiconductor material, e.g. silicon, germanium, etc. In an example embodiment, the substrate 100 may include, for example, silicon.

The amorphous layer 110 may be formed using a semiconductor material, e.g. silicon, germanium, etc. The amorphous layer 110 may be formed by, for example, a chemical vapor deposition (CVD) process using a silicon source gas, e.g. silane (SiH₄), silicon tetrachloride (SiCl₄), etc., or a germanium source gas, e.g. germane (GeH₄), germanium tetrachloride (GeCl₄), etc. Alternatively, the amorphous layer 110 may be formed by, for example, a sputtering process, a reduced pressure chemical vapor deposition (RPCVD) process, a low pressure chemical vapor deposition (LPCVD) process, a metal organic chemical vapor deposition (MOCVD) process, an atomic layer deposition (ALD) process, etc. The amorphous layer 110 may be formed at a temperature, for example, below about 450° C. In an example embodiment, the amorphous layer 110 may be formed to have a first thickness D1 of, for example, about 2 nm to about 100 nm.

Referring to FIG. 2, a first doping region 120 may be formed at an upper potion of the substrate 100, by, for example, implanting impurities through the amorphous layer 110.

The impurities may include, for example, boron, arsenic, phosphorous, etc. In an example embodiment, the first doping region 120 may be formed at the upper portion of the substrate 100, by, for example, implanting a boron ion onto the amorphous layer 110 with a dose of about 1×10¹²atoms/cm³ to about 5×10¹⁵atoms/cm³. The first doping region 120 may be formed to have a second thickness D2.

When implanting a relatively small sized ion, e.g. boron, into a silicon single crystalline layer, the forming of an impurity region having a relatively shallow depth and a high concentration may not be easy. However, in an example embodiment, the amorphous layer 110 may be formed on the substrate 100, so that the relatively small sized ion, e.g. boron, may not be deeply implanted into the substrate 100, thereby effectively forming the first doping region 120 which has a relatively shallow depth and a high impurity concentration.

Referring to FIG. 3, a second doping region 130 may be formed at an upper portion of the substrate 100, by, for example, performing a laser annealing process on the substrate 100 having the amorphous layer 110 thereon and having the first doping region 120 at the upper portion thereof. The amorphous layer 110 may be transformed into a recrystallized layer 140 by the laser annealing process.

The laser annealing process may be performed by, for example, irradiating a laser source, e.g. an excimer laser, onto a top surface of the amorphous layer 110. In an example embodiment, a laser having an energy of, for example, about 1 J/cm² to about 5 J/cm² may be irradiated onto the top surface of the amorphous layer 110. The energy range of the laser that may be irradiated onto the top surface of the amorphous layer 110 may be adjusted according to a concentration of the impurities and a thickness of the second doping region 130.

The second doping region 130 may be an impurity region implanted with a given concentration of, for example, boron, arsenic, or phosphorous. The second doping region 130 may be formed to have a third thickness D3 from a top surface of the substrate 100. In an example embodiment, the third thickness D3 of the second doping region 130 may be, for example, substantially larger than the second thickness D2 of the first doping region 120. That is, the impurities implanted in the first doping region 120 may diffuse into the substrate 100 during the laser annealing process, and thus the second doping region 130 may be formed more deeply than the first doping region 120.

For example, when implanting impurities by an ion implantation process, a heat treatment process may be further performed at a temperature of about 700° C. to about 900° C., thereby activating the impurities. However, in an example embodiment, the impurities in the second doping region 130 may be activated, for example, by performing a laser annealing process, instead of performing the heat treatment process at a high temperature.

The amorphous layer 110 on the substrate 100 may be, for example, crystallized to form a recrystallized layer 140 during the laser annealing process. A fourth thickness D4 of the recrystallized layer 140 may be, for example, substantially the same as or smaller than the first thickness D1 of the amorphous layer 110. In an example embodiment, the fourth thickness D4 of the recrystallized layer 140 may be, for example, in a range of about 2 nm to about 100 nm.

Referring to FIG. 4, the recrystallized layer 140 on the substrate 100 may be removed by, for example, an etching process or a polishing process. The etching process or the polishing process may include, for example, a chemical mechanical polishing process or a wet etching process. The second doping region 130 may be exposed by performing the etching process or the polishing process.

By performing the afore-mentioned processes, the second doping region 130 may be formed at the upper portion of the substrate 100.

According to an example embodiment, the amorphous layer 110 may be formed at the upper portion of the substrate 100 at a temperature, for example, below about 450° C., and the first doping region 120 may be formed by implanting impurities, e.g. boron, through the ion implantation process. The impurities in the first doping region 120 may be activated during the laser annealing process, so that the second doping region 130 may be formed to have a desired thickness. The laser annealing process may not be performed at a relatively high temperature, so that other elements on the substrate 100 may not be damaged by a high temperature process. Further, the impurities may not include a material including fluoride (F) such as, for example, boron fluoride (BF₂), so that a defect, e.g. slip dislocation, may not be generated in the substrate 100.

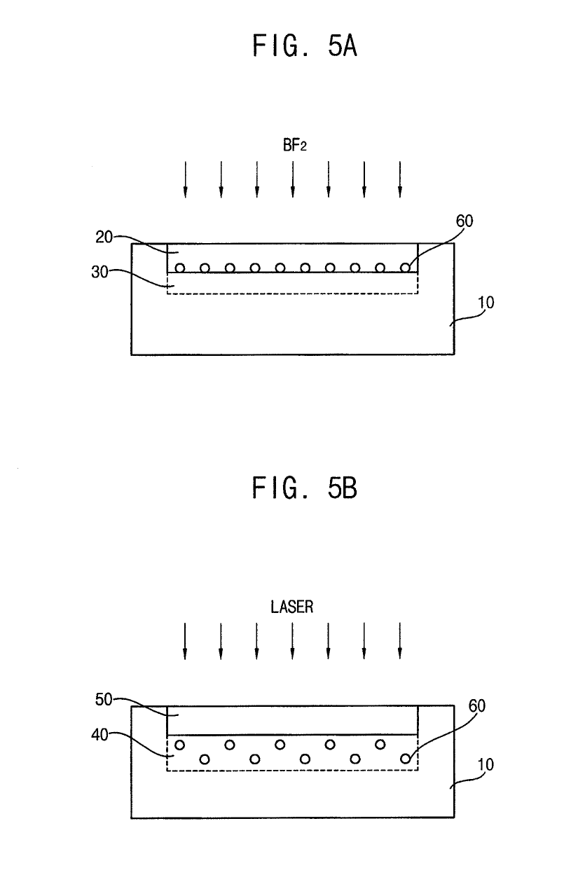

FIGS. 5A to 5B are cross-sectional views illustrating a method of implanting impurities in accordance with a comparative embodiment.

Referring to FIG. 5A, an amorphous layer 20 and a first doping region 30 may be formed at an upper portion of a substrate 10 by, for example, implanting impurities onto the substrate 10.

The substrate 10 may include, for example, silicon, germanium, or silicon germanium. The ion implantation process may be performed by, for example, using boron fluoride having relatively high energy. The thicknesses of the amorphous layer 20 and the first doping region 30 may be adjusted by controlling the energy of the boron fluoride. Further, a fluoride 60 may be located in the amorphous layer 20.

Referring to FIG. 5B, a laser annealing process may be performed on a top surface of the substrate 10 where the impurities may be implanted, so that a second doping region 40 may be formed.

The impurities implanted in the first doping region 30 may be activated during the laser annealing process, so that the first doping region 30 may extend into the substrate 10 to form the second doping region 40, and the amorphous layer 20 may be transformed into a recrystallized layer 50.

According to the comparative embodiment, the amorphous layer 20 and the first doping region 30 may be formed at the upper portion of the substrate 10 by, for example, implanting boron fluoride dopant into the substrate 10, and the impurities in the first doping region 30 may be activated during the laser annealing process. In this case, an implantation depth may not be large, so that the first doping region 30 may be formed to have a relatively thin thickness. However, using the boron fluoride dopant may cause a fluoride 60 to remain in the substrate 10, and thus a defect, e.g. slip dislocation, may be generated in the substrate 10.

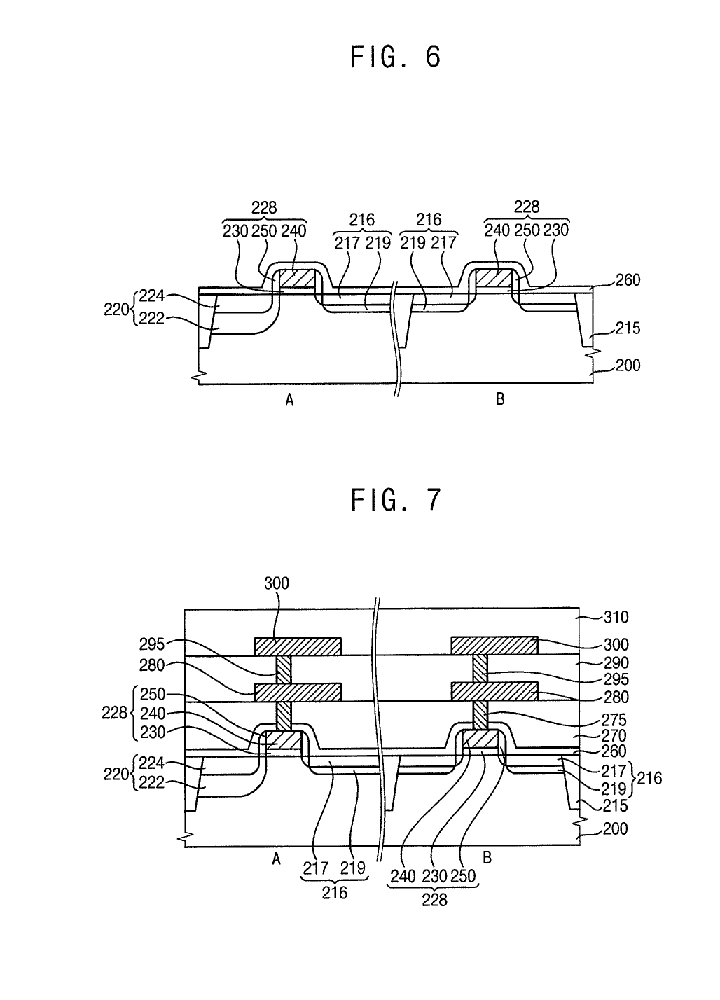

FIGS. 6 to 13 are cross-sectional views illustrating a method of manufacturing a CMOS image sensor in accordance with an example embodiment.

Referring to FIG. 6, an isolation layer 215 may be formed on a first substrate 200 including, for example, an active pixel sensor (APS) array region A and a peripheral circuit region B. A photodiode 220 and a first transistor may be formed in the APS array region A, and a second transistor may be formed in the peripheral circuit region B.

For example, the first substrate 200 may include a semiconductor material, e.g. silicon, germanium, etc., and the isolation layer 215 may be formed by a shallow trench isolation (STI) process using silicon oxide.

An insulation layer and a conductive layer may be formed on a first surface of the first substrate 200, and the insulation layer and the conductive layer may be patterned to form a gate insulation layer 230 and a gate electrode 240 in each of the APS array region A and the peripheral circuit region B. The insulation layer may be formed using, for example, an oxide, a nitride, or an oxynitride by a CVD process, a LPCVD process, a plasma enhanced chemical vapor deposition process, an ALD process, etc. The conductive layer may be formed using, for example, polysilicon doped with impurities, a metal, and/or a metal silicide by a CVD process, a high density plasma chemical vapor deposition process, an ALD process, etc.

Alternatively, after forming an epitaxial layer including, for example, silicon or germanium on the first substrate 200 by an epitaxial growth process, the isolation layer 215, the gate insulation layer 230 and gate electrode 240 may be formed on the epitaxial layer.

A first mask (not shown) partially exposing the APS array region A may be formed on the first substrate 200, and first impurities may be implanted into an upper portion of the first substrate 200 by, for example, an ion implantation process using the first mask as an ion implantation mask. In an example embodiment, an n-type impurity layer 222 may be formed by, for example, implanting n-type impurities. The n-type impurity layer 222 may be formed at upper portion of the first substrate 200 adjacent to a first sidewall of the gate electrode 240 in the APS array region A. The first mask may be removed.

A second mask (not shown) partially exposing the APS array region A and the peripheral circuit region B may be formed on the first substrate 200, and second impurities may be implanted into an upper portion of the first substrate 200. In an example embodiment, a low concentration impurity layer 217 may be formed by, for example, implanting a low concentration n-type impurity. The low concentration impurity layer 217 may be formed at, for example, an upper portion of the first substrate 200 adjacent to a second sidewall of the gate electrode 240 in the APS array region A and at an upper portion of the first substrate 200 adjacent to both sidewalls of the gate electrode 240 in the peripheral circuit region B. The second mask may be removed.

A spacer layer may be formed on the first substrate 200 to cover the gate electrode 240 and the gate insulation layer 230. The spacer layer may be patterned by, for example, an anisotropic etching process, thereby forming a spacer 250 on sidewalls of the gate electrode 240 and the gate insulation layer 230. The spacer 250 may be formed to include, for example, silicon nitride.

A third mask (not shown) partially exposing the APS array region A may be formed on the first substrate 200, and third impurities may be implanted into an upper portion of the first substrate 200 by, for example, an ion implantation process using the third mask and the spacer 250 as an ion implantation mask. For example, in an example embodiment, a p-type impurity layer 224 may be formed by implanting p-type impurities. The p-type impurity layer 224 may be formed at an upper portion of the n-type impurity layer 222, and thus the photodiode 220 may be formed to include the n-type impurity layer 222 and the p-type impurity layer 224 sequentially stacked. The third mask may be removed.

A fourth mask (not shown) partially exposing the APS array region A and the peripheral circuit region B may be formed on the first substrate 200, and fourth impurities may be implanted into an upper portion of the first substrate 200 by, for example, an ion implantation process using the fourth mask as an ion implantation mask. In an example embodiment, a high concentration impurity layer 219 may be formed by implanting high concentration n-type impurities. The high concentration impurity layer 219 may have a depth, for example, substantially deeper than that of the low concentration impurity layer 217, so that an impurity region 216 including the low concentration impurity layer 217 and the high concentration impurity layer 219 may have, for example, a lightly doped drain (LDD) structure. Alternatively, the impurity region 216 may include, for example, a single impurity layer.

The gate structures 228 may each include, for example, the gate electrode 240, the gate insulation layer 230 and the spacer 250 formed in the APS array region A and the peripheral circuit region B. The first transistor may include the gate structure 228 and the impurity region 216 formed in the APS array region A. In an example embodiment, the first transistor may serve as a transfer transistor. A plurality of the first transistors may be formed in the APS array region A, and these transistors may serve as a reset transistor, a drive transistor, and a select transistor, respectively. In FIG. 6, an impurity region 216 formed at the second sidewall of the gate structure in the APS array region A may serve as a floating diffusion region. The second transistor may include, for example, the gate structure 228 and the impurity region 216 in the peripheral circuit region B. In an example embodiment, a plurality of second transistors may be also formed in the peripheral circuit region B.

An etch stop layer 260 may be formed on the first substrate 200 to cover the gate structures. The etch stop layer 260 may be formed using, for example, silicon nitride.

Referring to FIG. 7, a first insulating interlayer 270 may be formed on the etch stop layer 260. A first opening (not shown) partially exposing the gate electrode 240 may be formed through the first insulating interlayer 270 and the etch stop layer 260. The first insulating interlayer 270 may be formed using an oxide, e.g. silicon oxide. A first conductive layer may be formed on the exposed gate electrode 240 and the first insulating interlayer 270 to fill the first opening, and the first conductive layer may be patterned to form a first plug 275 and a first wiring 280. The first plug 275 may fill the first opening, and the first wiring 280 connected to the first plug 275 may be formed on the first plug 275 and a portion of the first insulating interlayer 270. The first conductive layer may be formed using, for example, polysilicon doped with impurities, a metal and/or a metal nitride. A barrier layer (not shown) may be further formed on the exposed gate electrode 240 and a sidewall of the first opening using, for example, a metal nitride. In an example embodiment, the first plug 275 and the first wiring 280 may be formed using, for example, different conductive layers from each other, so that the first plug 275 and the first wiring 280 may include different materials from each other. Further, an opening (not shown) exposing the impurity region 216 may be formed, and a conductive layer (not shown) filling the opening may be formed on the exposed impurity region 216 and the first insulating interlayer 270. The conductive layer may then be patterned, thereby further forming a plug (not shown) and a wiring (not shown) which may be electrically connected to the impurity region.

A second insulating interlayer 290 may be formed on the first insulating interlayer 270 to cover the first wiring 280. A second opening (not shown) may be formed through the second insulating interlayer 290 to partially expose the first wiring 280. A second conductive layer may be formed on the exposed first wiring 280 and the second insulating interlayer 290 to fill the second opening, and the second conductive layer may be patterned to form a second plug 295 and a second wiring 300. The second plug 295 may fill the second opening, and the second wiring 300 connected to the second plug 295 may be formed on the second plug 295 and a portion of the second insulating interlayer 290. The second conductive layer may be formed using, for example, polysilicon doped with impurities, a metal and/or a metal nitride, and the second plug 295 and the second wiring 300 may be formed using different materials from each other.

A protection layer 310 may be formed on the second insulating interlayer 290 to cover the second wiring 300. The protection layer 310 may be formed using, for example, silicon oxide or silicon nitride.

Even though a wiring structure in FIG. 7 may include two levels, the scope of example embodiments the present inventive concept may not be limited thereto and include a wiring structure including more than two levels.

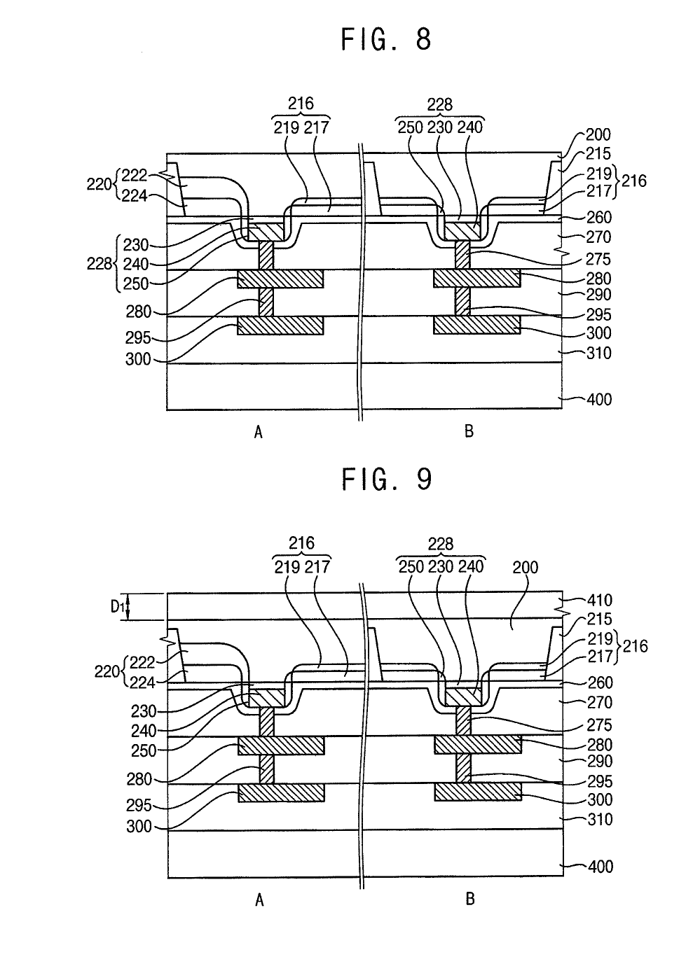

Referring to FIG. 8, a second substrate 400 may be formed on the protection layer 310. The second substrate 400 may include a semiconductor material, e.g. silicon, germanium, etc., or an insulation material. For the convenience of following processes, a structure including the first substrate 200, wirings and the second substrate 400 may be turned upside down.

A portion of a second surface of the first substrate 200, opposing the first surface, on which the wirings structure may not be formed may be removed. In an example embodiment, the removing process may include, for example, a grinding process, a CMP process, or a combination thereof In an example embodiment, a portion of the first substrate 200 may be removed by, for example, a grinding process, and the grinded surface of the first substrate 200 may be planarized by, for example, a CMP process. A thickness of the first substrate 200 may be adjusted according to an image pixel size. In an example embodiment, when the pixel size is about 1.75 um, the thickness of the first substrate 200 may be, for example, in a range of about 1 um to about 4 um. In this case, a dangling bond due to an incomplete bond between silicon and hydrogen may be generated on the grinded surface of the first substrate 200. Even if an optical signal does not come into the first substrate 200, electrons may be emitted from the dangling bond to apply a signal into a photodiode, so that a dark current or a white spot may occur. Therefore, the photosensitivity of a CMOS image sensor may be deteriorated. In a following process, a doping region implanted with p-type impurities may be formed at another portion of the first substrate 200, so that electrons emitted from the dangling bond may be recombined to suppress the occurrence of the dark current or the white spot.

Referring to FIG. 9, an amorphous layer 410 may be formed on the second surface of the first substrate 200 opposing the first surface. The amorphous layer 410 may be formed using a semiconductor material, e.g. silicon, germanium, etc. In an example embodiment, the amorphous layer 410 may be formed by, for example, a CVD process, a RPCVD process, a LPCVD process, an organic metal CVD process, a sputtering process, an ALD process, etc. In an example embodiment, the amorphous layer 410 may be formed at a temperature, for example, below about 450° C. In example embodiments, the amorphous layer 410 may be formed to have a thickness of, for example, about 2 nm to about 100 nm.

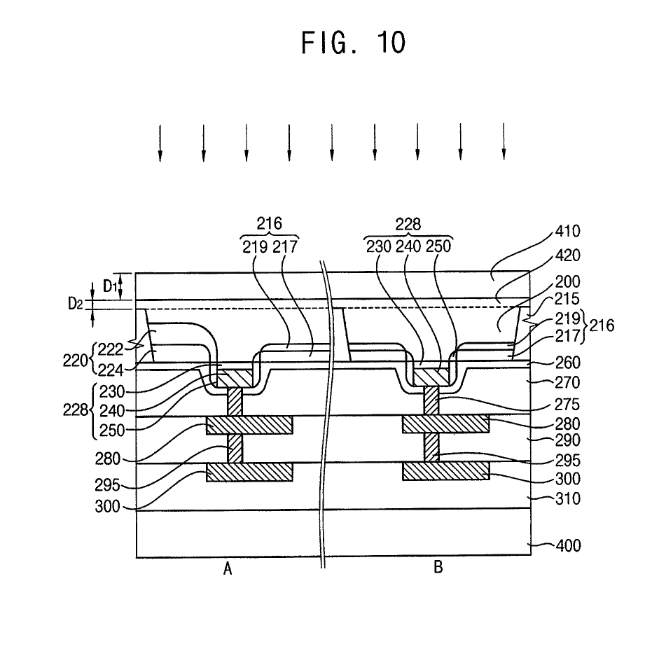

Referring to FIG. 10, a first doping region 420 may be formed at an upper portion of the second surface of the first substrate 200, by, for example, implanting impurities into the first substrate 200 through the amorphous layer 410.

The impurities may include, for example, boron, arsenic, phosphorous, etc. In an example embodiment, the first doping region 420 may be formed at the upper portion of the second surface of the first substrate 200, by, for example, implanting a boron ion onto the amorphous layer 410 with a dose of about 1×10¹² atoms/cm³ to about 5×10¹⁵ atoms/cm³. The first doping region 420 may be formed to have a second thickness D2.

When implanting a relatively small sized ion, e.g. boron, into a silicon single crystalline layer, the forming of an impurity region having a relatively shallow depth and a high concentration may not be easy. However, in an example embodiment, the amorphous layer 410 may be formed on the first substrate 200, so that the relatively small sized ion, e.g. boron, may not be deeply implanted into the first substrate 200, thereby effectively forming the first doping region 420 which has a relatively shallow depth and a high impurity concentration.

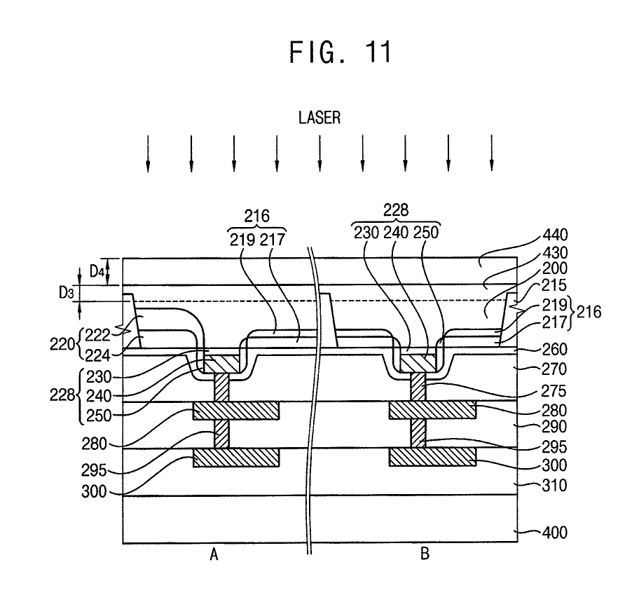

Referring to FIG. 11, a second doping region 430 may be formed at an upper portion of the second surface of the first substrate 200, by, for example, performing a laser annealing process on the upper portion of the second surface of the first substrate 200 having the amorphous layer 410 and the first doping region 420. The amorphous layer 410 may be transformed into a recrystallized layer 440.

The laser annealing process may be performed by, for example, irradiating a laser source, e.g. an excimer laser, onto a top surface of the amorphous layer 410. In an example embodiment, a laser having, for example, an energy of about 1 J/cm² to about 5 J/cm² may be irradiated onto the top surface of the amorphous layer 410. The energy range of the laser that may be irradiated onto the first substrate 200 may be adjusted according to a concentration of the impurities and a thickness of the second doping region 430.

The second doping region 430 may be an impurity region implanted with a given concentration of, for example, boron, arsenic, or phosphorous. The second doping region 430 may be formed to have a third thickness D3 from a top surface of the second surface of the first substrate 200. In an example embodiment, the third thickness D3 of the second doping region 430 may be, for example, substantially larger than the second thickness D2 of the first doping region 420. That is, the impurities implanted in the first doping region 420 may diffuse into the first substrate 200 during the laser annealing process, and thus the second doping region 430 may be formed to have a depth deeper than that of the first doping region 420.

For example, when implanting the impurities by an ion implantation process, a heat treatment process may be further performed at a temperature of about 700° C. to about 900° C., thereby activating the impurities. However, in an example embodiment, the impurities in the second doping region 430 may be activated by performing a laser annealing process, instead of performing the heat treatment process at the high temperature.

The amorphous layer 410 on second surface of the first substrate 200 may be crystallized to form a recrystallized layer 440 during the laser annealing process. A fourth thickness D4 of the recrystallized layer 440 may be adjusted depending on the energy of the laser. The fourth thickness D4 of the recrystallized layer 440 may be, for example, substantially the same as or smaller than the first thickness D1 of the amorphous layer 410. In an example embodiment, the fourth thickness D4 of the recrystallized layer 440 may be in a range of, for example, about 2 nm to about 100 nm.

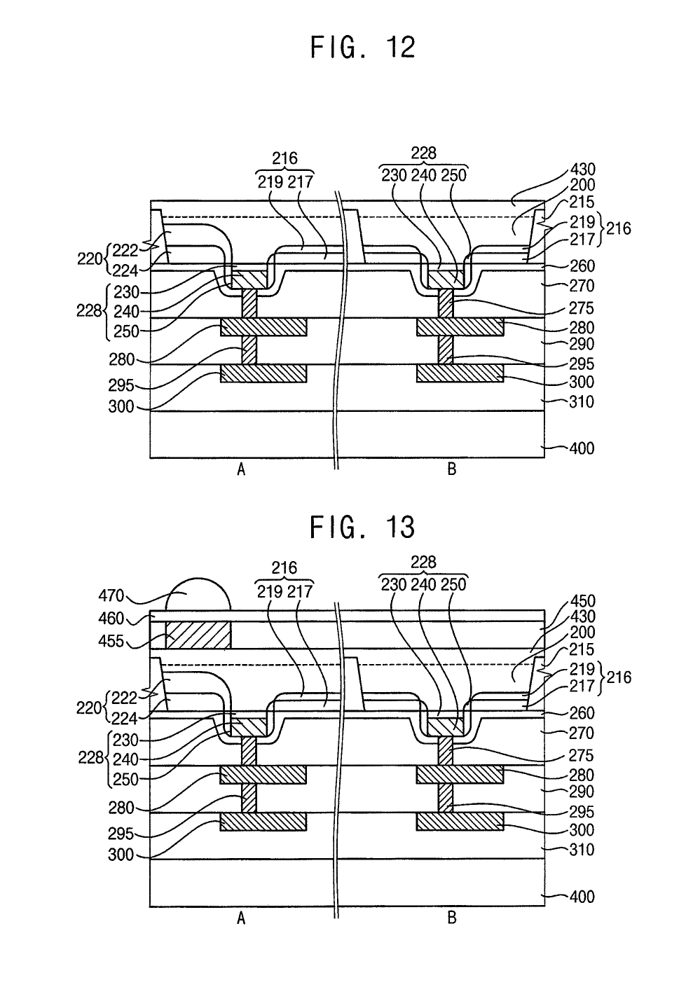

Referring to FIG. 12, the recrystallized layer 440 on the second surface of the first substrate 200 may be removed by, for example, an etching process or a polishing process.

The etching process or the polishing process may include, for example, a CMP process or a wet etching process. The second doping region 430 may be exposed by performing the etching process or the polishing process.

Referring to FIG. 13, an insulation layer 450 may be formed on the second surface of the first substrate 200 at which the second doping region 430 is formed, and a color filter 455 may be formed through the insulation layer 450 to overlap the photodiode 220. Even though, only one color filter 455 is illustrated in FIG. 13, at least three color filters 455 may be formed in the APS array region A.

A planarization layer 460 may be formed on the color filter 455 and the insulation layer 450, and a microlens 470 may be formed on the planarization layer 460 to overlap the color filter 455. By performing the afore-mentioned processes, the CMOS image sensor may be completed.

According to an example embodiment, the amorphous layer 410 may be formed on the second surface of the first substrate 200 at a temperature, for example, below about 450° C., and the first doping region 420 may be formed at the upper portion of the second surface of the first substrate 200 by implanting impurities, e.g. boron, through the ion implantation process. The impurities in the first doping region 420 may be activated during, for example, the laser annealing process, so that the second doping region 430 may be formed to have a desired thickness. The laser annealing process may not be performed at a relatively high temperature, so that other elements on the first substrate 200 may not be damaged by a high temperature process. Further, the impurities may not include a material including fluoride (F) such as, e.g. boron fluoride (BF₂), so that a defect, e.g. a slip dislocation, may not be generated in the first substrate 200. The second doping region 430 may remove electrons emitted from the dangling bond on the first substrate 200, and thus the occurrence of the dark current or the white spot may be suppressed.

Having described example embodiments of the present invention, it is further noted that it is readily apparent to those of reasonable skill in the art that various modifications may be made without departing from the spirit and scope of the invention which is defined by the metes and bounds of the appended claims.

What is claimed is:

1. A method of doping impurities comprising:
forming an amorphous layer on a substrate;
implanting impurities through a top surface of the amorphous layer to form a first doping region at an upper portion of the substrate;
transforming the first doping region and the amorphous layer into a second doping region and a recrystallized layer, respectively, by a laser annealing process; and
removing the recrystallized layer.

2. The method of claim 1, wherein the amorphous layer is formed at a temperature below about 450° C. by one of a chemical vapor deposition process, an atomic layer deposition process, or a sputtering process.

3. The method of claim 1, wherein the amorphous layer is formed to have a thickness of about 2 nm to about 100 nm.

4. The method of claim 1, wherein the amorphous layer is formed to include one of silicon, germanium, or silicon germanium.

5. The method of claim 1, wherein the impurities are formed of a material which does not include fluoride.

6. The method of claim 5, wherein the material of the impurities includes one of boron, arsenic, or phosphorous.

7. The method of claim 1, wherein the laser annealing process includes irradiating a laser having an energy of about 1 J/cm² to about 5 J/cm² onto the top surface of the amorphous layer.

8. The method of claim 1, wherein the second doping region has a thickness larger than a thickness of the first doping region.

9. A method of manufacturing a complementary metal oxide semiconductor (CMOS) image sensor comprising:
forming a photodiode and a circuit element on a first surface of a substrate, wherein the circuit element is electrically connected to the photodiode;
forming an amorphous layer on a second surface of the substrate opposing the first surface;
implanting impurities through a top surface of the amorphous layer to form a first doping region at an upper portion of the substrate;
transforming the first doping region and the amorphous layer into a second doping region and a recrystallized layer, respectively, by a laser annealing process; and
removing the recrystallized layer.

10. The method of claim 9, wherein prior to forming the amorphous layer on the second surface of the substrate, further comprising grinding the second surface of the substrate.

11. The method of claim 9, wherein after removing the recrystallized layer, further comprising forming a color filter and a microlens on the second surface of the substrate.

12. The method of claim 9, wherein the amorphous layer is formed using one of silicon, germanium, or silicon germanium at a temperature below about 450° C. by one of a chemical vapor deposition (CVD) process, an atomic layer deposition (ALD) process, or a sputtering process.

13. The method of claim 9, wherein the amorphous layer is formed to have a thickness of about 2 nm to about 100 nm.

14. The method of claim 9, wherein the impurities are formed of a material which includes one of boron, arsenic, or phosphorous.

15. The method of claim 9, wherein the laser annealing process includes irradiating a laser having an energy of about 1 J/cm² to about 5 J/cm²onto the top surface of the amorphous layer.

16. The method of claim 9, wherein the second doping region has a thickness larger than a thickness of the first doping region.

17. A method of manufacturing a complementary metal oxide semiconductor (CMOS) image sensor comprising:
forming a gate structure comprising a gate insulating layer and a gate electrode sequentially stacked on a first surface of a first substrate in each of an active pixel sensor array region and a peripheral circuit region of the first substrate;
forming a photodiode on the first surface of the first substrate in the active pixel sensor array region;
implanting first impurities into an upper portion of the first surface of the first substrate adjacent to a sidewall of the gate electrode in the active pixel sensor array region and into an upper portion of the first surface of the first substrate adjacent to opposing sidewalls of the gate electrode in the peripheral circuit region to form a first impurity region in the active pixel sensor array region and a second impurity region in the peripheral circuit region, wherein the gate structure and the first impurity region in the active pixel sensor array region are electrically connected to the photodiode;
forming a first insulating interlayer covering the gate electrodes in the active pixel sensor array region and the peripheral circuit region;
forming a first contact plug in the first insulating interlayer in the active pixel sensor array region and a first wiring connected to the first contact plug and on the first insulating interlayer and the first contact plug, wherein the first contact plug and the first wiring are electrically connected to the first impurity region in the active pixel sensor array region;
forming a second contact plug in the first insulating interlayer in the peripheral circuit region and a second wiring connected to the second contact plug and on the first insulating interlayer and the second contact plug, wherein the second contact plug and the second wiring are electrically connected to the second impurity region in the peripheral circuit region;
forming a protection layer on the first insulating interlayer to cover the first and second wirings in the active pixel sensor region and the peripheral circuit region;
forming a second substrate on a top surface of the protection layer;
turning the first substrate having the first and second wirings and the second substrate formed thereon upside down;
removing a portion of a second surface of the first substrate opposing the first surface;
forming an amorphous layer on the second surface of the first substrate at a temperature below about 450° C.;
implanting second impurities through a top surface of the amorphous layer to form a first doping region at the second surface of the first substrate, wherein the second impurities implanted into the top surface of the amorphous layer are formed of a material which does not include fluoride;
transforming the first doping region and the amorphous layer into a second doping region and a recrystallized layer, respectively, by a laser annealing process; and
removing the recrystallized layer.

18. The method of claim 17, wherein the photodiode is formed by implanting n-type impurities and p-type impurities into an upper portion of the first surface of the first substrate to form an n-type impurity layer and a p-type impurity layer sequentially stacked in the first substrate in the active pixel sensor array region, thereby forming the photodiode.

19. The method of claim 17, further comprising:
forming an insulation layer on the second doping region formed at the second surface of the first substrate;
forming a color filter through the insulation layer to overlap the photodiode;
forming a planarization layer on the color filter and the insulation layer; and
forming a microlens on the planarization layer to overlap the color filter.

20. The method of claim 17, wherein the material of the second impurities implanted into the top surface of the amorphous layer includes one of boron, arsenic, or phosphorous.
